(19) United States
(12) Patent Application Publication
(10) Pub. No.: US 2025/0056810 A1
(43) Pub. Date: Feb. 13, 2025

(54) SEMICONDUCTOR DEVICES WITH VERTICAL TRANSISTORS AND FERROELECTRIC CAPACITORS

(71) Applicant: Tokyo Electron Limited, Tokyo (JP)

(72) Inventors: Henry Jim FULFORD, Marianna, FL (US); Mark I. GARDNER, Austin, TX (US); Partha MUKHOPADHYAY, Oviedo, FL (US)

(73) Assignee: Tokyo Electron Limited, Tokyo (JP)

(21) Appl. No.: 18/448,086

(22) Filed: Aug. 10, 2023

(51) Int. Cl. H10B 53/30

(52) U.S. Cl. CPC H10B 53/30

(57) ABSTRACT

Semiconductor devices and corresponding methods of manufacture are disclosed. The semiconductor device includes a first semiconductor structure extending along a vertical direction; a high-k dielectric layer disposed around at least the first semiconductor structure; a first metal structure disposed around the first semiconductor structure, with the high-k dielectric layer interposed therebetween; a ferroelectric structure disposed around the first semiconductor structure, with the high-k dielectric layer and the first metal structure interposed therebetween; and a second metal structure having a portion disposed around the first semiconductor structure, with the high-k dielectric layer, the first metal structure, and the ferroelectric structure interposed therebetween.

### FIELD OF THE DISCLOSURE

This disclosure relates generally to semiconductor devices and methods of fabricating the same, and more specifically to vertical transistors with ferroelectric capacitors and methods of fabricating the same.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes.

Semiconductor device fabricators have expressed a desire for three-dimensional (3D) semiconductor circuits in which spacings between transistors or channels thereof are reduced. This reduction in spacings can be prevalent especially in the integration of memory devices. While efforts of such integration have been generally adequate to overcome scaling limitations experienced in planar devices, they are not entirely satisfactory in all aspects.

### SUMMARY

One aspect of the present disclosure is directed to a semiconductor device. The semiconductor device includes a first semiconductor structure extending along a vertical direction; a high-k dielectric layer disposed around at least the first semiconductor structure; a first metal structure disposed around the first semiconductor structure, with the high-k dielectric layer interposed therebetween; a ferroelectric structure disposed around the first semiconductor structure, with the high-k dielectric layer and the first metal structure interposed therebetween; and a second metal structure having a portion disposed around the first semiconductor structure, with the high-k dielectric layer, the first metal structure, and the ferroelectric structure interposed therebetween.

In some embodiments, the first metal structure comprises a top surface and a bottom surface, each of the top surface and the bottom surface having a staircase profile. The ferroelectric structure comprises a first portion lining the top surface of the first metal structure and a second portion lining the bottom surface of the first metal structure.

In some embodiments, the semiconductor further includes a second semiconductor structure in contact with a bottom surface of the first semiconductor structure; and a third second semiconductor structure in contact with a top surface of the first semiconductor structure. The first semiconductor structure has a first conductivity, while the second and third semiconductor structures have a second conductivity. The high-k dielectric layer is disposed around also the third semiconductor structure.

In some embodiments, the semiconductor further includes a first contact structure in electrical connection with the second semiconductor structure; and a second contact structure in electrical connection with the third semiconductor structure. The first contact structure has a lateral portion around the second semiconductor structure, and a vertical portion in parallel with a combination of the second semiconductor structure, the first semiconductor structure, and the third semiconductor structure. The second contact structure is wrapped by the high-k dielectric layer.

In some embodiments, the second metal structure, the ferroelectric structure, and the first metal structure operatively form a first capacitor with a first capacitance, and the first metal structure, the high-k dielectric layer, and the first semiconductor structure operatively form a second capacitor with a second capacitance. The first capacitance is substantially greater than the second capacitance.

Another aspect of the present disclosure is directed to a memory device. The memory device includes a memory cell consisting of a transistor and a capacitor. The transistor includes a first semiconductor structure extending along a vertical direction; a second semiconductor structure disposed below the first semiconductor structure; a third semiconductor structure disposed above the first semiconductor structure; a high-k dielectric layer surrounding at least the first semiconductor structure and the third semiconductor structure; and a first metal structure surrounding the first semiconductor structure, with the high-k dielectric layer interposed therebetween. The capacitor includes the first metal structure; a ferroelectric structure surrounding the first semiconductor structure, with the high-k dielectric layer and the first metal structure interposed therebetween; and a second metal structure having a portion surrounding the first semiconductor structure, with the high-k dielectric layer, the first metal structure, and the ferroelectric structure interposed therebetween.

In some embodiments, the first metal structure comprises a top surface and a bottom surface, each of the top surface and the bottom surface having a staircase profile. The ferroelectric structure comprises a first portion lining the top surface of the first metal structure and a second portion lining the bottom surface of the first metal structure.

In some embodiments, the first semiconductor structure has a first conductivity, while the second and third semiconductor structures have a second conductivity.

In some embodiments, the memory device further includes a first contact structure in electrical connection with the second semiconductor structure; and a second contact structure in electrical connection with the third semiconductor structure. The first contact structure has a lateral portion surrounding the second semiconductor structure, and a vertical portion in parallel with a combination of the second semiconductor structure, the first semiconductor structure, and the third semiconductor structure.

Yet another aspect of the present disclosure is directed to a method for fabricating semiconductor devices. The method includes vertically etching a stack comprising a first dielectric layer, a second dielectric layer, and a third dielectric layer to form a vertical opening. The method includes laterally etching the second dielectric layer to form a recess. The method includes forming a first metal structure lining an inner sidewall of the recess, a first portion of a top surface of the recess, and a first portion of a bottom surface of the recess. The method includes forming a ferroelectric structure lining an inner sidewall of the first metal structure, a second portion of the top surface of the recess, and a second portion of the bottom surface of the recess. The method includes forming a second metal structure filling the recess. The method includes lining an inner sidewall of the vertical opening with a high-k dielectric layer. The method includes forming a first semiconductor structure inside the vertical opening that is wrapped by the high-k dielectric layer, the second metal structure, the ferroelectric structure, and the first metal structure.

In some embodiments, the method further includes prior to lining the inner sidewall of the vertical opening with the high-k dielectric layer, epitaxially growing a second semiconductor structure; and subsequently to forming the first semiconductor structure, epitaxially growing a third semiconductor structure. The method further includes forming a first contact structure in electrical connection with the second semiconductor structure, wherein the first contact structure comprises a lateral portion surrounding the second semiconductor structure; and forming a second contact structure in electrical connection with the third semiconductor structure, wherein the second contact structure is disposed above the third semiconductor structure.

These and other aspects and implementations are discussed in detail below. The foregoing information and the following detailed description include illustrative examples of various aspects and implementations and provide an overview or framework for understanding the nature and character of the claimed aspects and implementations. The drawings provide illustrations and a further understanding of the various aspects and implementations and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIGS. 1A-1B collectively illustrate a flowchart of a method for making a semiconductor structure, according to an embodiment;

FIGS. 2A-18 show various views of an example semiconductor structure at various fabrication stages, according to various embodiments;

FIG. 19 illustrates a cross-sectional view of a semiconductor device, according to an embodiment; and

FIG. 20 illustrates a cross-sectional view of a semiconductor device, according to an embodiment.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Disclosed herein are embodiments related to semiconductor devices including one or more memory cells and methods for fabricating the same. In various embodiments, each of the disclosed memory cells can consist of a vertical transistor and a ferroelectric capacitor, which are sometimes collectively referred to as a ferroelectric field-effect-transistor (FeFET). For example, the vertical transistor, including its source/drain structures (or contacts) vertically disposed below and above a vertically extending semiconductor channel, respectively, may be formed through one or more growth/deposition processes in a vertical opening. Given the geometry of the semiconductor channel, the vertical transistor can have a first metal structure surrounding the semiconductor channel, which functions as a gate structure (or contact) of the vertical transistor. A ferroelectric structure can further surround the first metal structure, with a second metal structure further surrounding the ferroelectric structure. As such, the first metal structure, the ferroelectric structure, and the second metal structure can function as the ferroelectric capacitor coupled to the vertical transistor. Further, the ferroelectric structure can be formed to have a staircase profile along each of its top and bottom surfaces, which can advantageously increase a capacitance value of the ferroelectric capacitor. As such, a programming and/or retention capability of the disclosed memory cell can be improved.

Reference will now be made to the figures, which for the convenience of visualizing such three-dimensional (3D) fabrication techniques described herein, illustrate a substrate undergoing a process flow. Unless expressly indicated otherwise, each figure represents one (or a set) of fabrication steps in a process flow for manufacturing the devices described herein. In the figures, connections between conductive layers or materials may be shown. However, it should be understood that these connections between various layers and masks are merely illustrative and are intended to show a capability for providing such connections and should not be considered limiting to the scope of the claims.

Likewise, although the figures and aspects of the disclosure may show or describe devices herein as having a particular shape, it should be understood that such shapes are merely illustrative and should not be considered limiting to the scope of the techniques described herein. For example, although certain figures show various layers defining transistor structures or other electric structures in a rectangular configuration, other shapes are also contemplated, and indeed the techniques described herein may be implemented in any shape or geometry.

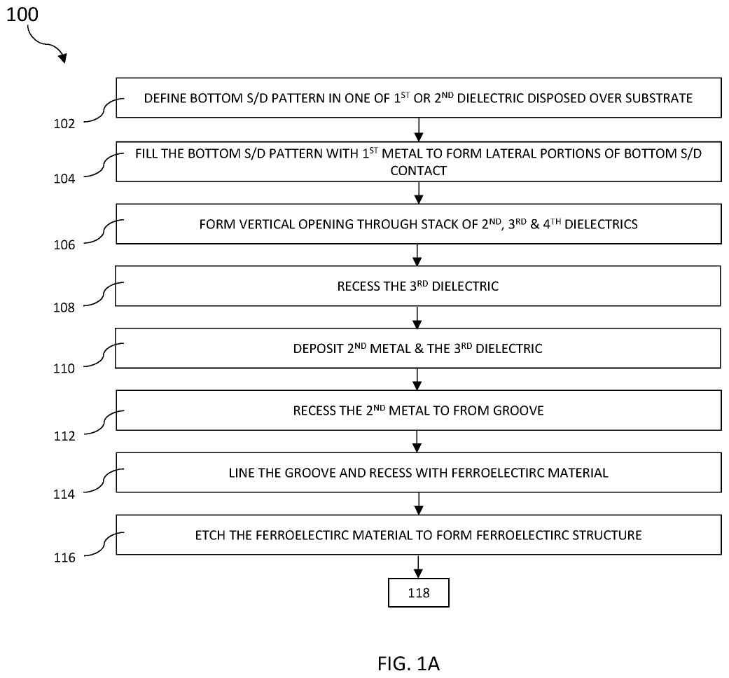

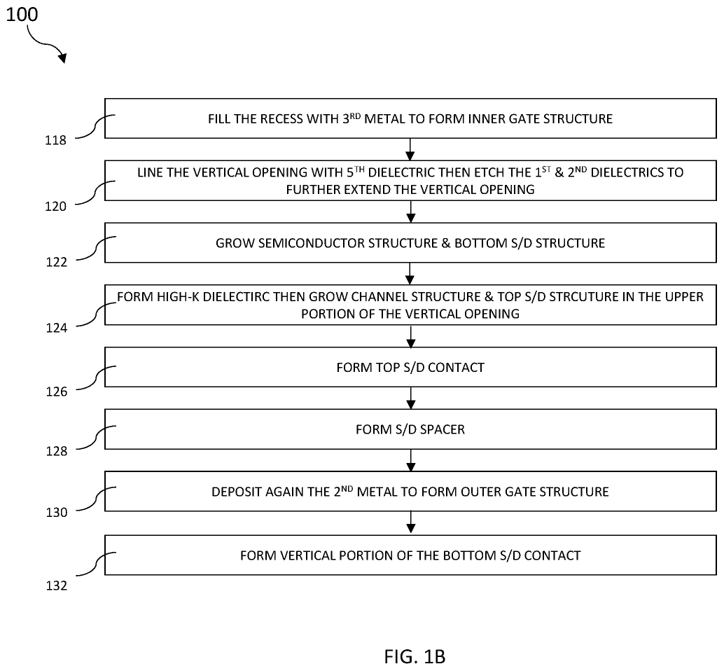

FIGS. 1A-1B collectively illustrate a flowchart of a method 100 for making a semiconductor structure (e.g., a vertical transistor and a ferroelectric capacitor), in accordance with various embodiments of the present disclosure. It is noted that the method 100 is merely an example and is not intended to limit the present disclosure. Accordingly, it is understood that additional operations may be provided before, during, and after the method 100 of FIGS. 1A-1B, and that some other operations may only be briefly described herein.

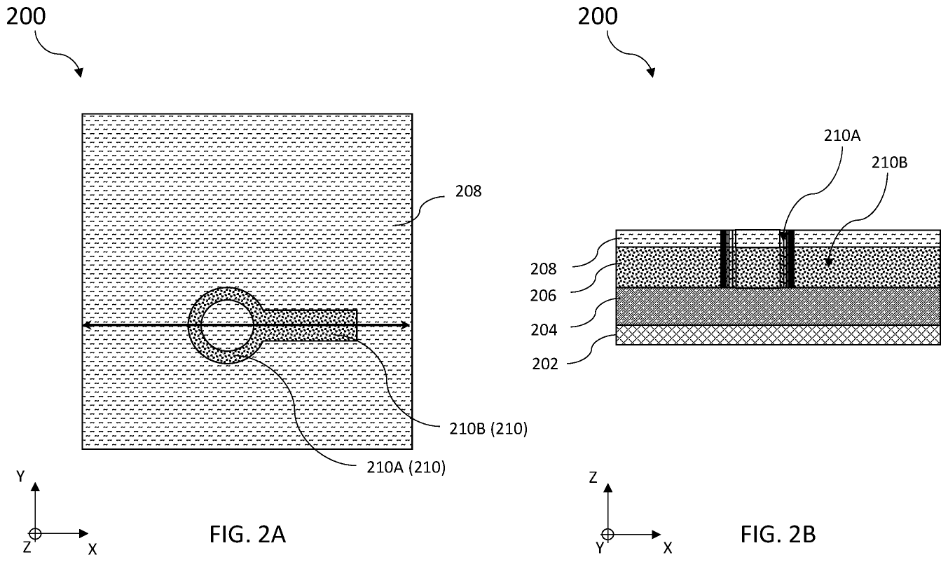

In various embodiments, operations of the method 100 may be associated with top, cross-sectional, or perspective views of an example semiconductor structure (also referred to herein as a semiconductor device) 200 at various fabrication stages as shown in FIGS. 2A-18, which will be discussed in further detail below. It should be understood that the semiconductor device 200, shown in FIGS. 2A-18, may include a number of other devices such as inductors, fuses, capacitors, coils, etc., while remaining within the scope of the present disclosure.

Referring to FIGS. 1A and 2A-2B, the method 100 starts with operation 102 in which a bottom source/drain pattern 210 is defined in a second dielectric (layer) 206 that is disposed over a first dielectric (layer) 204 that is disposed over a semiconductor substrate 202, at one of various fabrication stages, in accordance with various embodiments. FIG. 2A illustrates a top view of the semiconductor device 200, and FIG. 2B illustrates a corresponding cross-sectional view of the semiconductor device 200 cut along line B-B indicated in FIG. 2A.

The semiconductor substrate 202 includes a semiconductor material substrate, for example, silicon. Alternatively, the semiconductor substrate 202 may include other elementary semiconductor material such as, for example, germanium. The semiconductor substrate 202 may also include a compound semiconductor such as silicon carbide, gallium arsenic, indium arsenide, and indium phosphide. The semiconductor substrate 202 may include an alloy semiconductor such as silicon germanium, silicon germanium carbide, gallium arsenic phosphide, and gallium indium phosphide. In one embodiment, the semiconductor substrate 202 includes an epitaxial layer. For example, the semiconductor substrate 202 may have an epitaxial layer overlying a bulk semiconductor. Furthermore, the semiconductor substrate 202 may include a semiconductor-on-insulator (SOI) structure. For example, the semiconductor substrate 202 may include a buried oxide (BOX) layer formed by a process such as separation by implanted oxygen (SIMOX) or other suitable technique, such as wafer bonding and grinding.

The first dielectric 204 and second dielectric 206 are sequentially disposed (e.g., deposited) along the Z direction to form a stack. In some embodiments, the first dielectric 204 and second dielectric 206 exhibit etching selectivity with respect to one another. Upon forming the stack (of the first dielectric 204 and second dielectric 206), a patternable layer (e.g., a photoresist) 208 is formed over the second dielectric 206. The patternable layer 208 can be defined with a pattern transferred to the second dielectric 206. Given the etching selectivity, the pattern may be formed in the second dielectric 206 only. For example, in FIGS. 2A-B, a pattern, including a first portion and second portion, is defined in the patternable layer 208, and is then transferred to the second dielectric 206 through one or more (e.g., directional) etching processes to form the bottom source/drain pattern 210. Such etching processes can be stopped by the first dielectric 204. In some embodiments, the bottom source/drain pattern 210 includes a first portion 210A and a second portion 210B, in which the first portion 210A forms a ring-based shape with the second portion 210B extending away from an outer edge of the first portion 210A along the X direction.

The first dielectric 204 and second dielectric 206 may each include an oxide, a nitride, a low-k dielectric material, the like, or combinations thereof. The first dielectric 204 and second dielectric 206 may each be deposited using any suitable method, such as CVD, HDP-CVD, FCVD, the like, or combinations thereof.

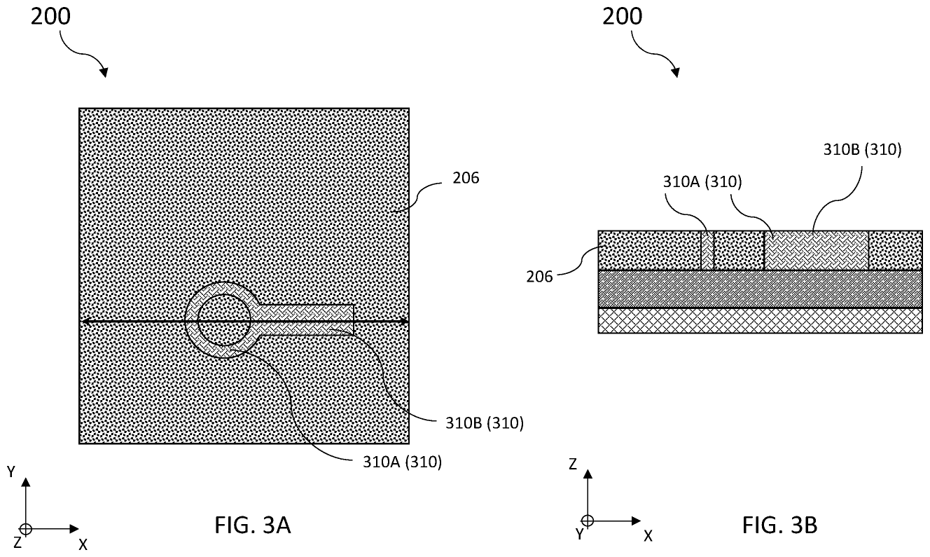

Referring to FIGS. 1A and 3A-3B, the method 100 proceeds to operation 104 in which the bottom source/drain pattern 210 is filled with a first metal 310, at one of various fabrication stages, in accordance with various embodiments. FIG. 3A illustrates a top view of the semiconductor device 200, and FIG. 3B illustrates a corresponding cross-sectional view of the semiconductor device 200 cut along line B-B indicated in FIG. 3A.

The first metal 310 may include any suitable conductive material (e.g., a metal), such as tungsten, copper, aluminum, ruthenium, cobalt, silver, gold, the like, or combinations thereof. The first metal 310 may be deposited using any suitable process, such as CVD, PVD, ALD, electroplating, electroless plating, the like, or combinations thereof. Following the formation of the first metal 310, a chemical-mechanical polishing (CMP) process may be performed to remove excessive first metal 310 (and the patternable layer 208). In some embodiments, the first metal 310 can fill the first portion 210A and the second portion 210B to form lateral portions of a bottom source/drain contact (structure), which are hereinafter referred to as “lateral portion of bottom source/drain contact 310A” and “lateral portion of bottom source/drain contact 310B,” respectively.

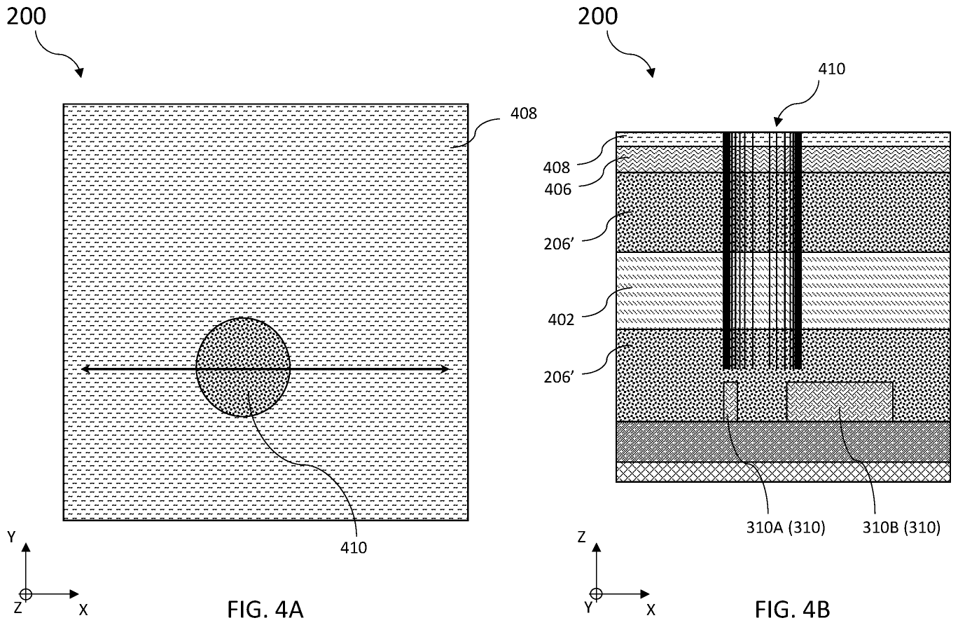

Referring to FIGS. 1A and 4A-4B, the method 100 proceeds to operation 106 in which a vertical opening 410 is formed through a stack of another second dielectric ((layer)) 206′, third dielectric (layer) 402, and fourth dielectric (layer) 406, at one of various fabrication stages, in accordance with various embodiments. FIG. 4A illustrates a top view of the semiconductor device 200, and FIG. 4B illustrates a corresponding cross-sectional view of the semiconductor device 200 cut along line B-B indicated in FIG. 4A.

Following the formation of the lateral portions of bottom source/drain contact 310A and 310B, a stack consisting of another second dielectric 206′, third dielectric 402, yet another second dielectric 206′, and fourth dielectric 406 is deposited over the second dielectric 206 that surrounds the lateral portions of bottom source/drain contact 310A and 310B. Next, a pattern is defined in a patternable layer 408, and is then transferred to such a stack through one or more (e.g., directional) etching processes to form the vertical opening 410. Such etching processes may be stopped at a middle of the second dielectric 206 and 206′, as shown in FIG. 4B. Stated another way, the lateral portions of bottom source/drain contact 310A and 310B may remained overlaid by the second dielectric 206 or 206′ after forming the vertical opening 410.

The third dielectric 402 and fourth dielectric 406 may each include an oxide, a nitride, a low-k dielectric material, the like, or combinations thereof. The third dielectric 402 and fourth dielectric 406 may each be deposited using any suitable method, such as CVD, HDP-CVD, FCVD, the like, or combinations thereof. In some embodiments, the third dielectric 402 and second dielectric 206 exhibit etching selectivity with respect to one another.

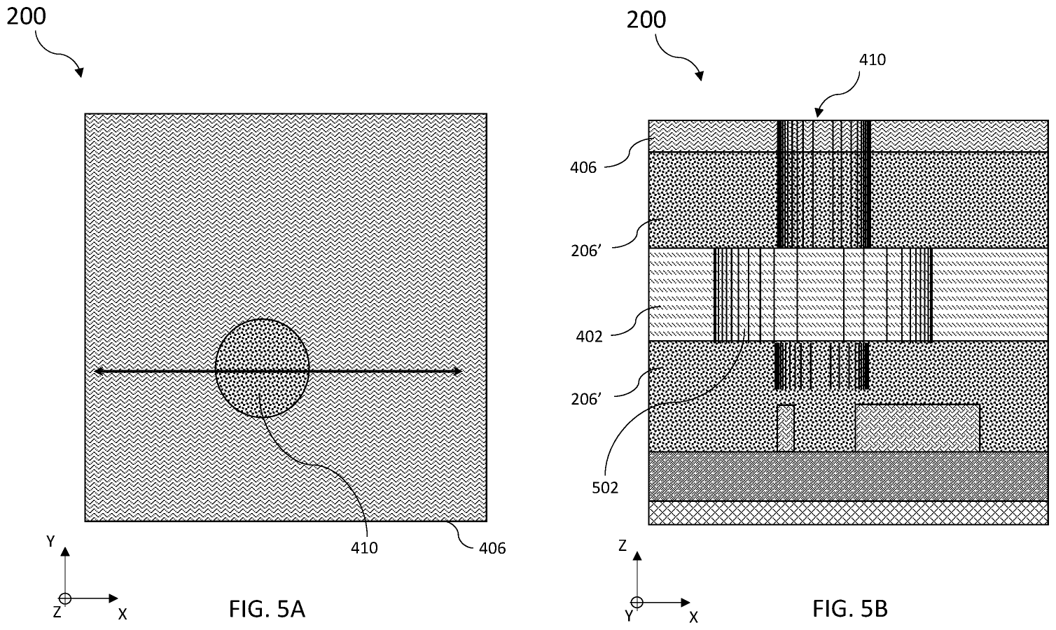

Referring to FIGS. 1A and 5A-5B, the method 100 proceeds to operation 108 in which the third dielectric 402 is recessed, at one of various fabrication stages, in accordance with various embodiments. FIG. 5A illustrates a top view of the semiconductor device 200, and FIG. 5B illustrates a corresponding cross-sectional view of the semiconductor device 200 cut along line B-B indicated in FIG. 5A.

A selective etching process may be performed to etch the third dielectric 402 to form a recess 502 through the vertical opening 410. The second dielectric 206/206′ may remain substantially intact through the etching process. As shown in the example of FIG. 5B, the recess 502 is formed by outwardly radially extending the vertical opening 410 only at the portion aligned with the third dielectric 402. In other words, the recess 502 can have its sidewall misaligned with a sidewall of the vertical opening 410 along the Z direction.

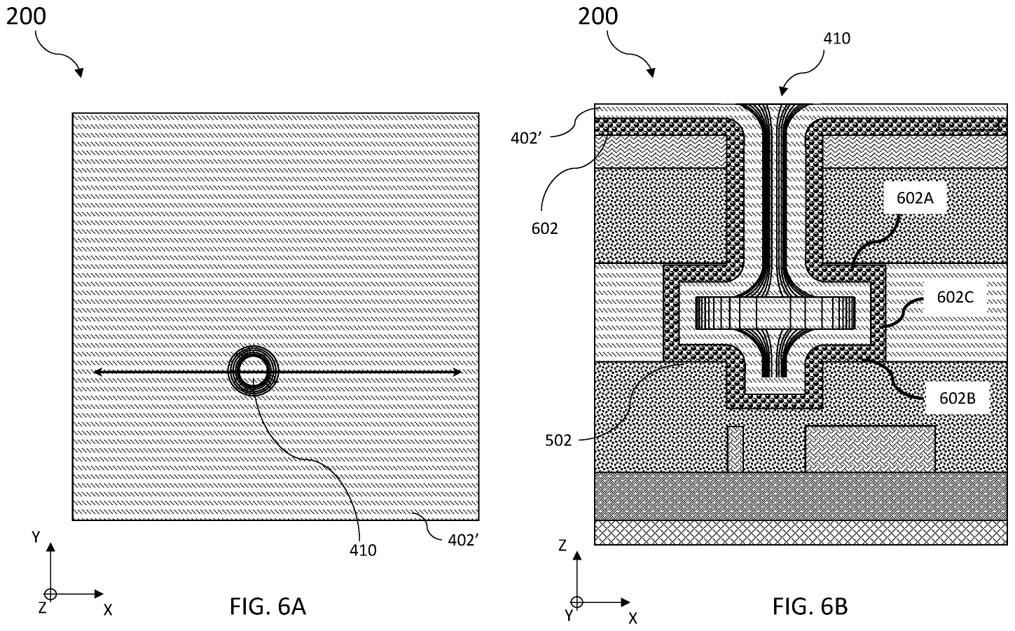

Referring to FIGS. 1A and 6A-6B, the method 100 proceeds to operation 110 in which a second metal (layer) 602 and another third dielectric (layer) 402′ are sequentially deposited, at one of various fabrication stages, in accordance with various embodiments. FIG. 6A illustrates a top view of the semiconductor device 200, and FIG. 6B illustrates a corresponding cross-sectional view of the semiconductor device 200 cut along line B-B indicated in FIG. 6A.

In some embodiments, the second metal 602 and the third dielectric 402′ may each be formed as a conformal layer (e.g., with a thickness substantially less than a diameter of the vertical opening 410). As a result, the second metal 602 and the third dielectric 402′ may each follow a collective profile of the vertical opening 410 and the recess 502. For example, in FIG. 6B, the second metal 602 can line a top surface, a bottom surface, and the sidewall of the recess 502 to form portions 602A, 602B, and 602C, respectively. Such portions 602A-C, upon being further processed, can operatively serve as an outer gate structure of the semiconductor device 200, which will be discussed below. The second metal 602 may include any suitable conductive material (e.g., a metal), such as tungsten, copper, aluminum, ruthenium, cobalt, silver, gold, the like, or combinations thereof. The second metal 602 may be deposited using any suitable process, such as CVD, PVD, ALD, electroplating, electroless plating, the like, or combinations thereof.

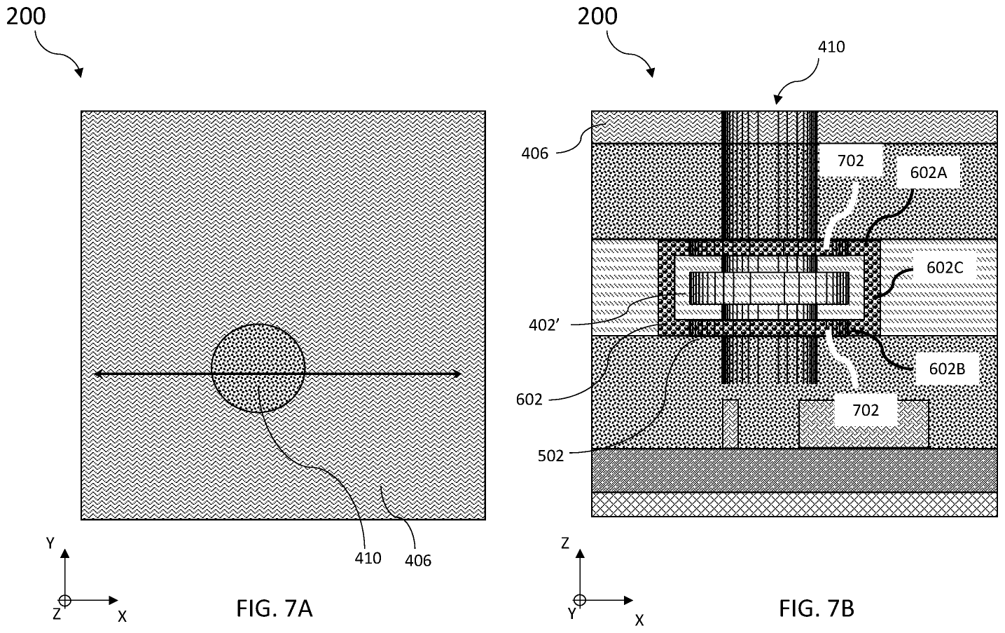

Referring to FIGS. 1A and 7A-7B, the method 100 proceeds to operation 112 in which portions of the second metal 602 are etched to form a groove 702, at one of various fabrication stages, in accordance with various embodiments. FIG. 7A illustrates a top view of the semiconductor device 200, and FIG. 7B illustrates a corresponding cross-sectional view of the semiconductor device 200 cut along line B-B indicated in FIG. 7A.

In some embodiments, at least portions of the third dielectric 402′ and the second metal 602 that extend along the sidewall of the vertical opening 410 may be first removed through a (e.g., directional) etching process. As such, the vertical opening 410 can expose the portions 602A and 602B. Next, a selective etching process may be performed to recess the portions 602A and 602B (with a remaining portion of the third dielectric 402′ substantially intact), thereby forming the groove 702. Stated another way, the portions 602A and 602B may each be shortened along the X direction. The third dielectric 402′ is then removed by selective etching.

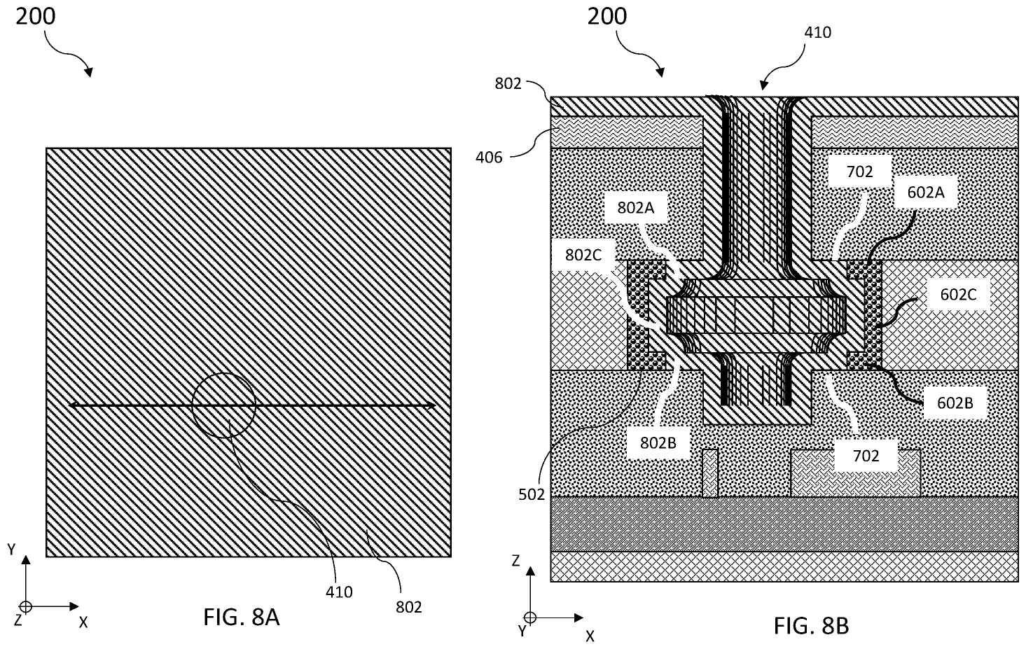

Referring to FIGS. 1A and 8A-8B, the method 100 proceeds to operation 114 in which a ferroelectric material (layer) 802 is formed to line at least the groove 702 and the recess 502, at one of various fabrication stages, in accordance with various embodiments. FIG. 8A illustrates a top view of the semiconductor device 200, and FIG. 8B illustrates a corresponding cross-sectional view of the semiconductor device 200 cut along line B-B indicated in FIG. 8A.

The ferroelectric material 802 is deposited as a conformal layer. As a result, the ferroelectric material 802 can line the vertical opening 410, the recess 502, and the groove 702 to present a top staircase profile and a bottom staircase profile in the recess 502. For example, in FIG. 8B, the ferroelectric material 802 includes a first portion 802A contacting a combination of the portions 602A and 602C to have a surface presenting the top staircase profile, and a second portion 802B contacting a combination of the portions 602B and 602C to have a surface presenting the bottom staircase profile. In addition, the ferroelectric material 802 includes a third portion 802C contacting the portion 602C.

The ferroelectric material 802 may include hafnium oxide (e.g., hafnium oxide containing at least one dopant selected from Al, Zr, and Si and having a ferroelectric non-centrosymmetric orthorhombic phase), zirconium oxide, hafnium-zirconium oxide, bismuth ferrite, barium titanate (e.g., BaTiO₃ (BT)), colemanite (e.g., Ca₂B₆O₁₁·5H₂O), bismuth titanate (e.g., Bi₄Ti₃O₁₂), europium barium titanate, ferroelectric polymer, germanium telluride, langbeinite (e.g., M₂M′₂ (SO₄)₃ in which M is a monovalent metal and M′ is a divalent metal), lead scandium tantalate (e.g., Pb(ScₓTa₁₋ₓ)O₃), lead titanate (e.g., PbTiO₃ (PT)), lead zirconate titanate (e.g., Pb(Zr,Ti)O₃ (PZT)), lithium niobate (e.g., LiNbO₃ (LN)), lanthanum aluminate (LaAlO₃), polyvinylidene fluoride ((CH₂CF₂)ₙ), potassium niobate (e.g., KNbO₃), potassium sodium tartrate (e.g., KNaC₄H₄O₆·4H₂O), potassium titanyl phosphate (e.g., KO₅PTi), sodium bismuth titanate (such as Na_{0.5}Bi_{0.5}TiO₃ or Bi_{0.5}Na_{0.5}TiO₃), lithium tantalate (such as LiTaO₃ (LT)), lead lanthanum titanate (e.g., (Pb,La) TiO₃(PLT)), lead lanthanum zirconate titanate (e.g., (Pb,La)(Zr,Ti)O₃ (PLZT)), ammonium dihydrogen phosphate (such as NH₄H₂PO₄(ADP)), or potassium dihydrogen phosphate (e.g., KH₂PO₄ (KDP)). The ferroelectric material 802 may be deposited using any suitable process, such as ALD, CVD, PVD, the like, or combinations thereof.

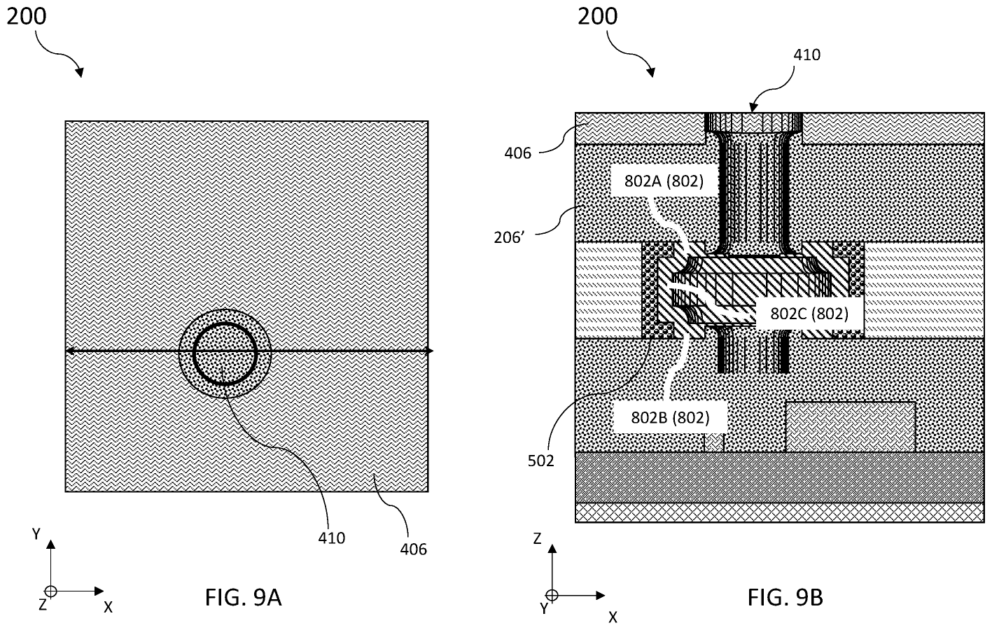

Referring to FIGS. 1A and 9A-9B, the method 100 proceeds to operation 116 in which the ferroelectric material 802 is etched to form a ferroelectric structure (hereinafter “ferroelectric structure 802”), at one of various fabrication stages, in accordance with various embodiments. FIG. 9A illustrates a top view of the semiconductor device 200, and FIG. 9B illustrates a corresponding cross-sectional view of the semiconductor device 200 cut along line B-B indicated in FIG. 9A.

Following the deposition of the ferroelectric material 802, a directional (e.g., vertical) etching process may be performed to remove at least portions of the ferroelectric material 802 that extends along the sidewall and a bottom surface of the vertical opening 410. As such, the remaining ferroelectric material 802 (e.g., the first portion 802A and second portion 802B) may be aligned with the sidewall of the vertical opening 410 that is exposed again. In some embodiments, additional second dielectric 206′ may be grown along the sidewall of the vertical opening 410 to cover at least some of the respective sidewalls of the first portion 802A and second portion 802B.

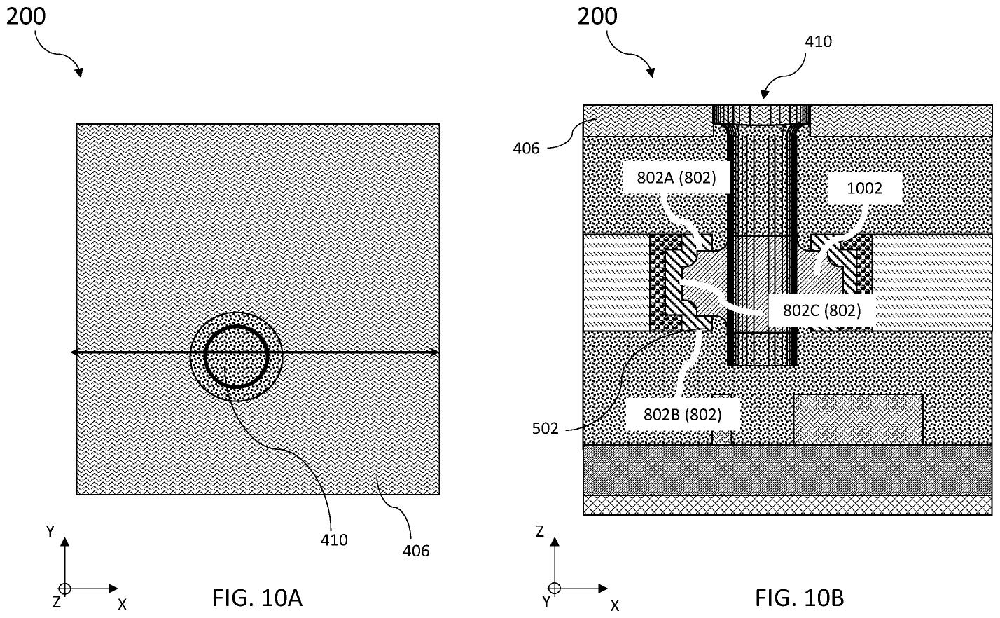

Referring to FIGS. 1B and 10A-10B, the method 100 proceeds to operation 118 in which a third metal (layer) 1002 is filled the remaining recess 502 so as to form an inner gate structure of the semiconductor device 200 (hereinafter “inner gate structure 1002”), at one of various fabrication stages, in accordance with various embodiments. FIG. 10A illustrates a top view of the semiconductor device 200, and FIG. 10B illustrates a corresponding cross-sectional view of the semiconductor device 200 cut along line B-B indicated in FIG. 10A.

The inner gate structure 1002 may be formed by depositing the third metal to fill some of the vertical opening 410, followed by a directional (e.g., vertical) etching process. As such, the inner gate structure 1002 can follow the staircase profiles of the ferroelectric structure 802. The third metal 1002 may include any suitable conductive material (e.g., a metal), such as tungsten, copper, aluminum, ruthenium, cobalt, silver, gold, the like, or combinations thereof. The third metal 1002 may be deposited using any suitable process, such as CVD, PVD, ALD, electroplating, electroless plating, the like, or combinations thereof.

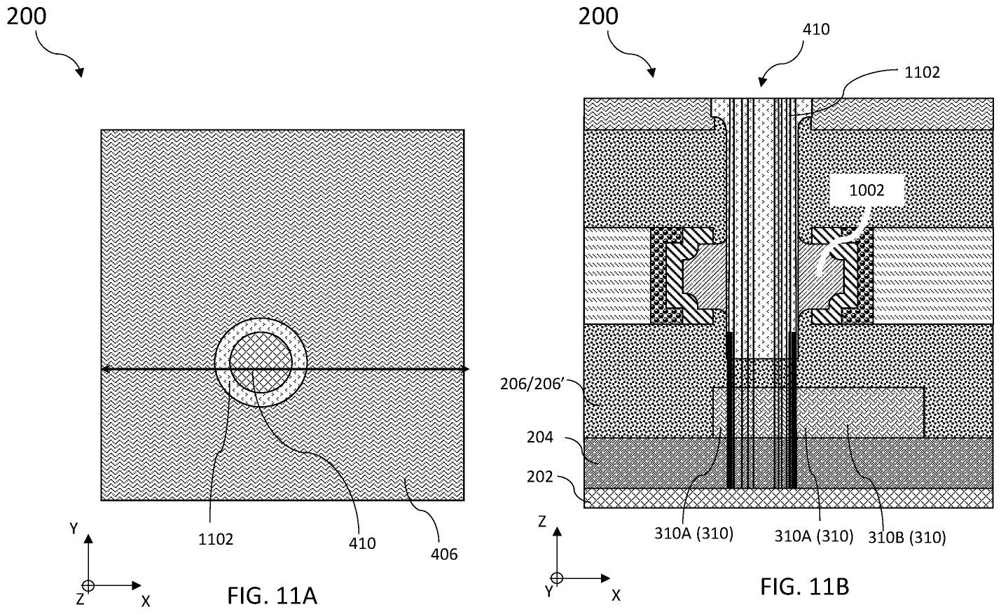

Referring to FIGS. 1B and 11A-11B, the method 100 proceeds to operation 120 in which a fifth dielectric (layer) 1102 is deposited to surround the vertical opening 410 (FIG. 10B) and the vertical opening 410 is further downwardly extended by etching the second dielectric 206/206′ and the first dielectric 204, at one of various fabrication stages, in accordance with various embodiments. FIG. 11A illustrates a top view of the semiconductor device 200, and FIG. 11B illustrates a corresponding cross-sectional view of the semiconductor device 200 cut along line B-B indicated in FIG. 11A.

In some embodiments, the fifth dielectric 1102 may be first deposited to surround the vertical opening 410 (FIG. 10B). The fifth dielectric 1102 may be formed as a conformal layer to line sidewalls of the vertical opening 410. Such a fifth dielectric 1102 may have a bottom surface vertically below a lowest point of the inner gate structure 1002. Next, a directional (e.g., vertical) etching process is performed to etch the second dielectric 206/206′ and the first dielectric 204 so as to further extend the vertical opening 410. The etching process may be stopped by the semiconductor substrate 202. Accordingly, at this fabrication stage, the vertical opening 410 may have its upper portion wrapped by the fifth dielectric 1102, and its lower portion exposed, wherein a junction between the lower portion and the upper portion is disposed vertically below the inner gate structure 1002. Further, the lower portion of the vertical opening 410 can be surrounded by the lateral portion of bottom source/drain contact 310A formed as a ring-shape.

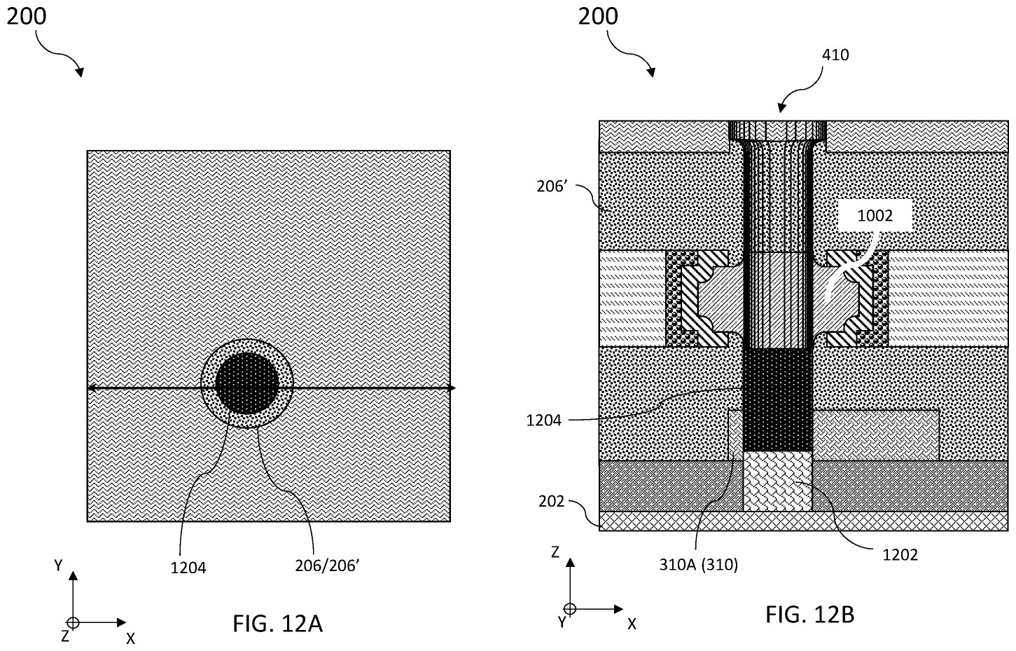

Referring to FIGS. 1B and 12A-12B, the method 100 proceeds to operation 122 in which a semiconductor structure 1202 and a bottom source/drain structure 1204 are sequentially formed in the lower portion of the vertical opening 410, at one of various fabrication stages, in accordance with various embodiments. FIG. 12A illustrates a top view of the semiconductor device 200, and FIG. 12B illustrates a corresponding cross-sectional view of the semiconductor device 200 cut along line B-B indicated in FIG. 12A.

In the example where the semiconductor substrate 202 includes silicon, the semiconductor structure 1202 may include silicon germanium, which may be epitaxially grown from the semiconductor substrate 202, and the bottom source/drain structure 1204 may include silicon, which may be epitaxially grown from the semiconductor structure 1202. In some embodiments, at least a portion of the bottom source/drain structure 1204 is surrounded by the ring-shaped lateral portion of bottom source/drain contact 310A, and top surface of the bottom source/drain structure 1204 may be formed below the lowest point of the inner gate structure 1002. In some embodiments, the bottom source/drain structure 1204 may have first conductivity (e.g., n-type).

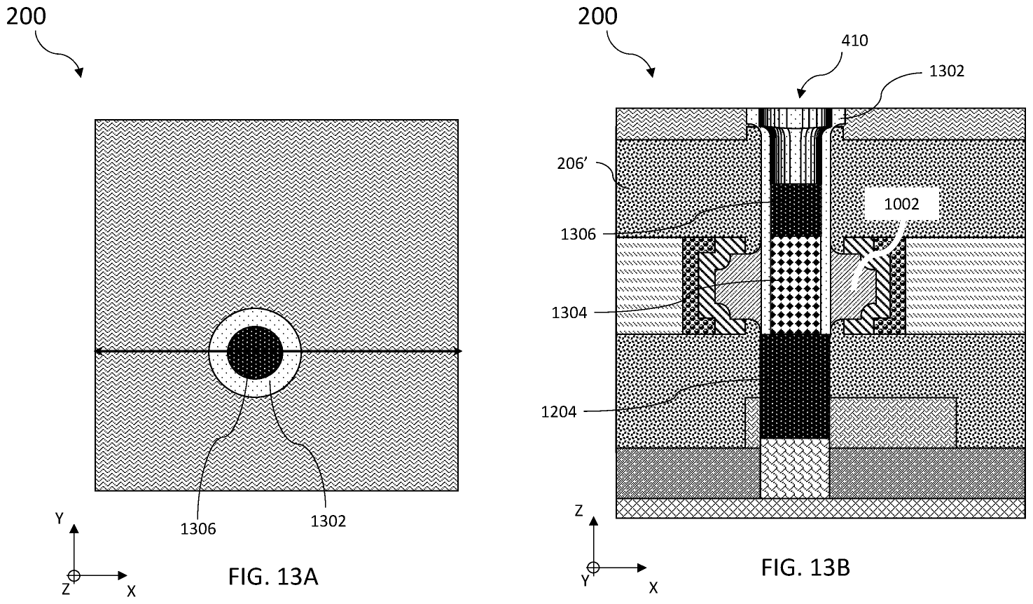

Referring to FIGS. 1B and 13A-13B, the method 100 proceeds to operation 124 in which a high-k dielectric (layer) 1302 is formed to line the upper portion of the vertical opening 410, followed by epitaxial growth of a channel structure 1304 and a top source/drain structure 1306, at one of various fabrication stages, in accordance with various embodiments. FIG. 13A illustrates a top view of the semiconductor device 200, and FIG. 13B illustrates a corresponding cross-sectional view of the semiconductor device 200 cut along line B-B indicated in FIG. 13A.

After forming the channel structure 1204 in the lower portion of the vertical opening 410, the high-k dielectric 1302 is first deposited to line the upper portion of the vertical opening 410. Next, the channel structure 1304 may include silicon with second conductivity (e.g., p-type), which may be epitaxially grown from the bottom source/drain structure 1204, and the top source/drain structure 1306 may include silicon with the first conductivity (e.g., n-type), which may be epitaxially grown from the channel structure 1304. In various embodiments, the channel structure 1304 may be controlled to have a height or longitudinal length that is greater than a height of the inner gate structure 1002. As such, the channel structure 1304 can be wrapped by the inner gate structure 1002 with the high-k dielectric 1302 interposed therebetween.

The high-k dielectric 1302 may include a metal oxide or a silicate of hafnium, aluminum, zirconium, lanthanum, magnesium, barium, titanium, lead, the like, or combinations thereof. The high-k dielectric 1302 may include a stack of different dielectric materials. The high-k dielectric 1302 may be deposited using any suitable process, such as ALD, CVD, PECVD, PVD, the like, or combinations thereof.

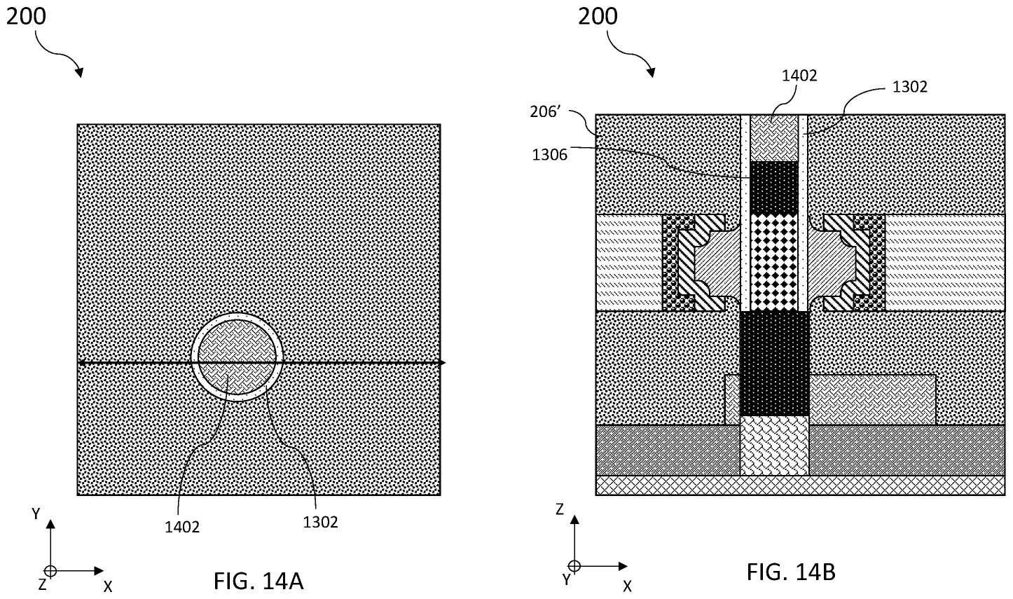

Referring to FIGS. 1B and 14A-14B, the method 100 proceeds to operation 126 in which a top source/drain contact (structure) 1402 is formed, at one of various fabrication stages, in accordance with various embodiments. FIG. 14A illustrates a top view of the semiconductor device 200, and FIG. 14B illustrates a corresponding cross-sectional view of the semiconductor device 200 cut along line B-B indicated in FIG. 14A.

The top source/drain contact 1402 may be formed by filling the rest of the vertical opening 410 with the first metal 310. The first metal 310 may be deposited using any suitable process, such as CVD, PVD, ALD, electroplating, electroless plating, the like, or combinations thereof. Following the formation of the first metal 310, a chemical-mechanical polishing (CMP) process may be performed to remove excessive first metal 310. As such, the top source/drain contact 1402 is formed to contact the top source/drain structure 1306.

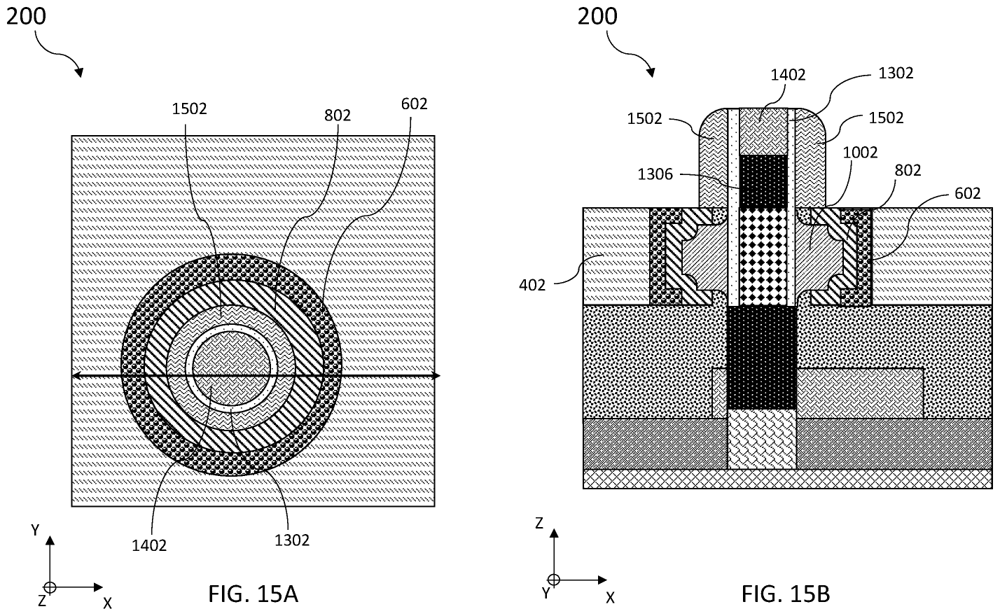

Referring to FIGS. 1B and 15A-15B, the method 100 proceeds to operation 128 in which a source/drain spacer 1502 is formed, at one of various fabrication stages, in accordance with various embodiments. FIG. 15A illustrates a top view of the semiconductor device 200, and FIG. 15B illustrates a corresponding cross-sectional view of the semiconductor device 200 cut along line B-B indicated in FIG. 15A.

Following the formation of the top source/drain contact 1402 (FIG. 14B), the second dielectric 206′ may be removed through an etching process. In some embodiments, the etching process may be anisotropic or isotropic, and the etching process may be stopped by the third dielectric 402. As such, the ferroelectric structure 802 and the second metal 602 can be exposed. Next, the fourth dielectric 406 can be again deposited, followed by a directional etching process, thereby forming the source/drain spacer 1502 as shown in FIG. 15B. The source/drain spacer 1502 may be configured to electrically isolate the top source/drain contact 1402 and top source/drain structure 1306 from an outer gate structure, formed of the second metal 602, which will be discussed as follows.

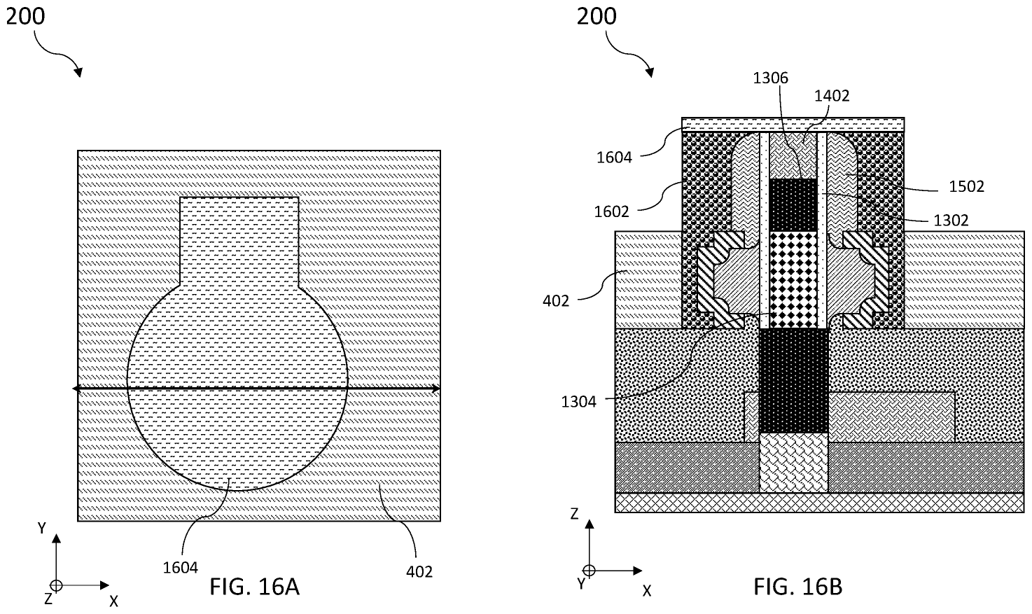

Referring to FIGS. 1B and 16A-16B, the method 100 proceeds to operation 130 in which an outer gate structure 1602 is formed, at one of various fabrication stages, in accordance with various embodiments. FIG. 16A illustrates a top view of the semiconductor device 200, and FIG. 16B illustrates a corresponding cross-sectional view of the semiconductor device 200 cut along line B-B indicated in FIG. 16A.

After the second metal 602 is exposed (FIG. 15B), the second metal 602 may be again deposited, followed by a patterning (e.g., etching) process through a patternable layer 1604. The patterning process may be stopped by the third dielectric 402. As a result, the second metals 602 can merge to form the outer gate structure 1602. As shown in FIG. 16B, the outer gate structure 1602 may have (i) a lower portion surrounding the channel structure 1304, with the high-k dielectric 1302 interposed therebetween; and (ii) an upper portion surrounding the top source/drain contact 1402 and top source/drain structure 1306, with the high-k dielectric 1302 and the source/drain spacer 1502 interposed therebetween.

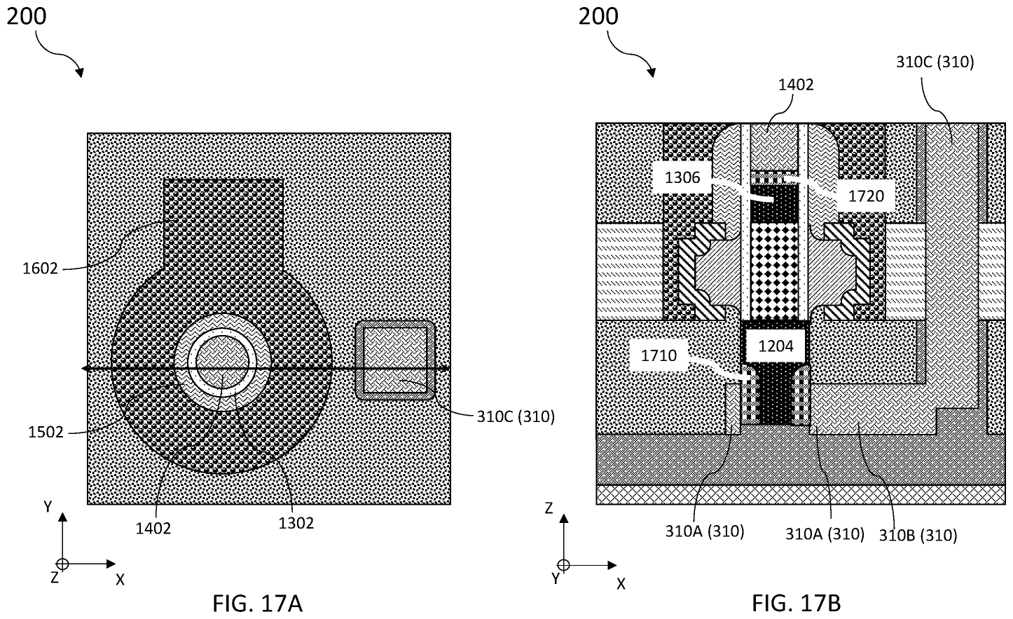

Referring to FIGS. 1B and 17A-17B, the method 100 proceeds to operation 132 in which a vertical portion of bottom source/drain contact 310C is formed, at one of various fabrication stages, in accordance with various embodiments. FIG. 17A illustrates a top view of the semiconductor device 200, and FIG. 17B illustrates a corresponding cross-sectional view of the semiconductor device 200 cut along line B-B indicated in FIG. 17A.

The vertical portion of bottom source/drain contact 310C may be formed by filling another vertical opening laterally next to the outer gate structure 1602 with the first metal 310. The vertical portion of bottom source/drain contact 310C may be in contact with the lateral portion of bottom source/drain contact 310B. Silicide regions (e.g., 1710, 1720) may be formed by heating the structure to cause a reaction between the source/drain structure 1204 and the metal of 310A as well as between the source/drain structure 1306 and the metal of 1402.

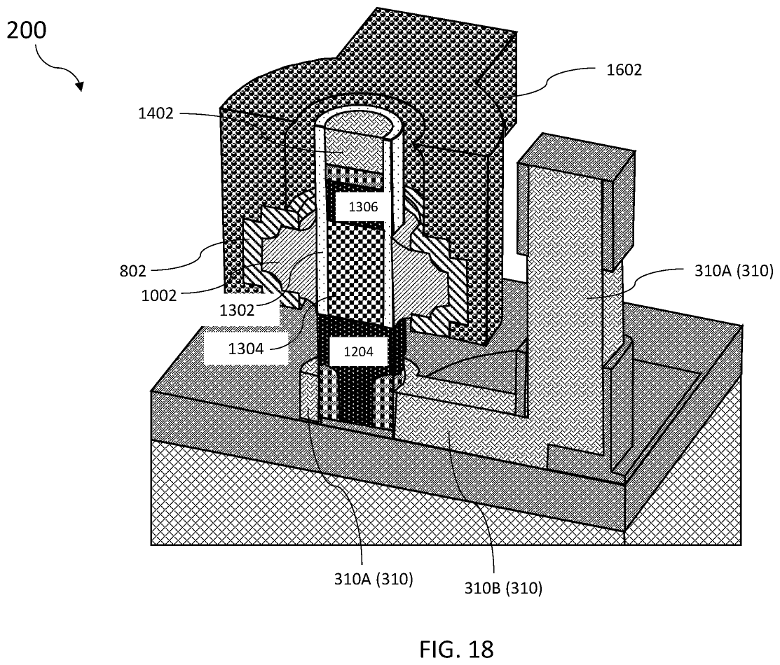

To better illustrate such a three-dimensional structure, FIG. 18 is a perspective view of the semiconductor device 200 (e.g., after the vertical portion of bottom source/drain contact 310C is formed), in accordance with various embodiments. As shown, the inner gate structure 1002 surrounds the channel structure 1304, with the high-k dielectric 1302 interposed therebetween, and the channel structure 1304 has its two ends (along the Z direction) connected to the source/drain structures 1204 and 1306, respectively. The source/drain structures 1204 and 1306 are further connected to (or accessed by) the contacts 310 and 1402, respectively. In some embodiments, the inner gate structure 1002, the high-k dielectric 1302, the channel structure 1304, and the source/drain structures 1204 and 1306 can operatively form a vertical transistor. Other than the vertical transistor, the inner gate structure 1302, the ferroelectric structure 802, and the outer gate structure 1602 can operatively form a ferroelectric capacitor.

Such a ferroelectric capacitor is coupled to a gate of the vertical transistor, which can operatively form a memory cell (e.g., an FeFET). The ferroelectric capacitor can operatively serve as a memory portion of the memory cell to store information. In general, a ferroelectric material refers to a material that displays spontaneous polarization of electrical charges (e.g., dipoles) in the absence of an applied electric field. The dipole moment of the ferroelectric material is programmed in two different orientations (e.g., “up” or “down” polarization positions based on atom positions, such as oxygen and/or metal atom positions, in the crystal lattice), depending on the polarity of the applied electric field, to store information in the ferroelectric material. The different orientations of the dipole moment of the ferroelectric material may be detected by the electric field generated by the dipole moment of the ferroelectric material. In the present embodiments, the semiconductor device 200 can relies on the ferroelectric structure 802 to store information in a plurality of non-volatile memory cells.

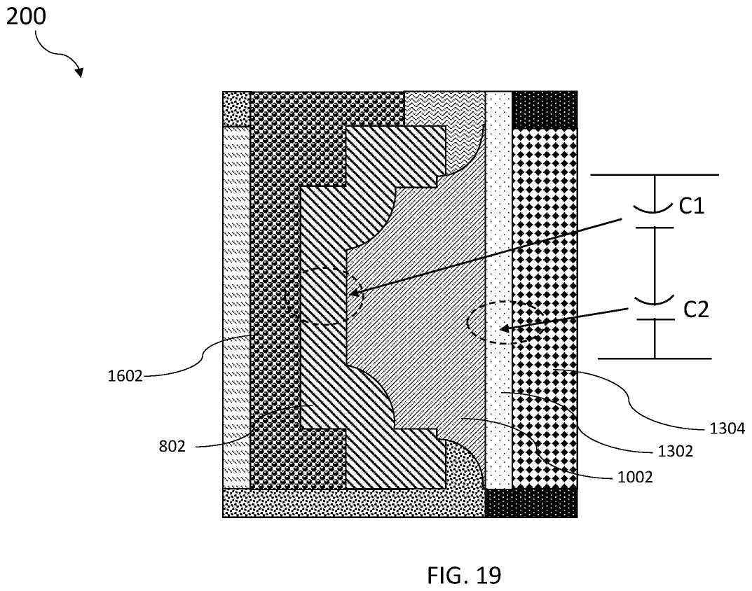

Further, the ferroelectric structure 802 is formed as having one or more staircase profiles, which can significantly increase a contact area between the ferroelectric structure 802 and each of the inner gate structure 1302 and the outer gate structure 1602. Accordingly, a capacitance value of the ferroelectric capacitor can be advantageously increased. FIG. 19 illustrates an enlarged, cross-sectional view of a portion of the semiconductor device 200 including the ferroelectric capacitor serially connected to another capacitance. As shown, the ferroelectric capacitor (formed by the inner gate structure 1002, the ferroelectric structure 802, and the outer gate structure 1602) has a capacitance value “C₁” and another capacitor (formed by the inner gate structure 1002, the high-k dielectric 1302, and the channel structure 1304) has a second capacitance value “C₂.” With the staircase profiles, C₁ may be substantially greater than C₂. As a non-limiting example, C₁ may be three times greater than C₂. As such, a programming and/or retention capability of the disclosed memory cell can be significantly improved.

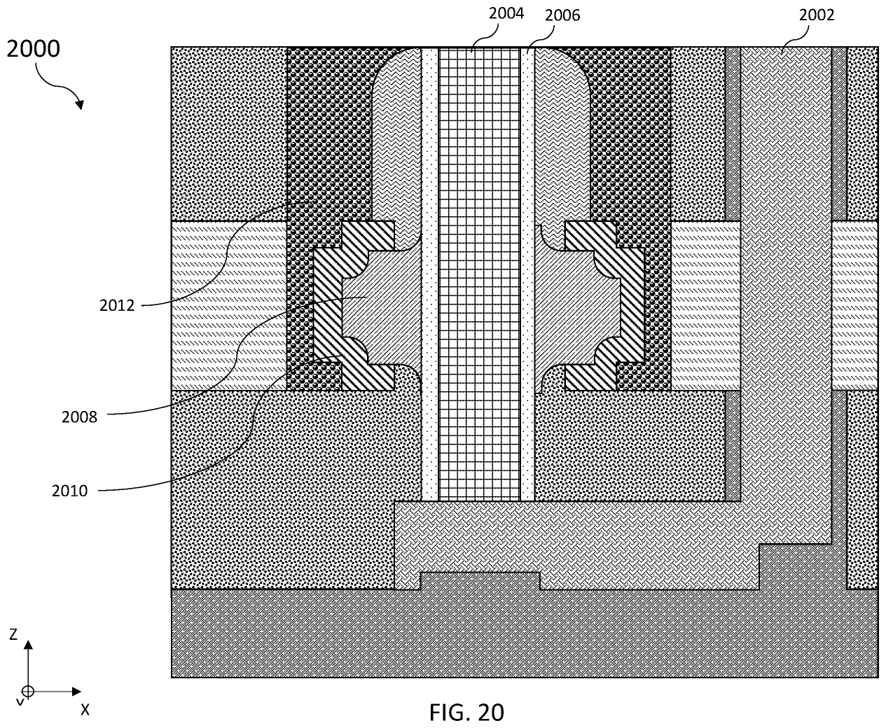

Based on at least some of the operations of the method 100 discussed with respect to FIG. 1, another semiconductor device including a junction-less vertical transistor and a ferroelectric capacitor can be formed. FIG. 20 illustrates a cross-sectional view of such a semiconductor device 2000, in accordance with various embodiments. The semiconductor device 2000 may be similar to the semiconductor device 200 (FIGS. 2A-19) except that the semiconductor device 2000 includes other material configured as its channel structure, and has no (e.g., semiconductor) junction between the channel structure and its source or drain structure. Accordingly, the following discussion will be focused on the difference.

As shown, the semiconductor device 2000 includes a bottom source/drain contact 2002, a channel structure 2004, a high-k dielectric 2006, an inner gate structure 2008, a ferroelectric structure 2010, and an outer gate structure 2012. In some embodiments, the channel structure 2004 may include a conductive oxide. Examples of the conductive oxides include indium gallium zinc oxide (IGZO), indium tin oxide (ITO), indium zinc oxide (IZO), indium tungsten oxide (IWO), zinc oxide (ZnO), indium oxide (In₂O₃), tin oxide (SnO₂), the like, or combinations thereof. With the conductive oxide implemented as the channel structure 2004, it may not be necessary to form respective source/drain structures, and accordingly, the channel structure 2004 may extend all the way from the bottom source/drain contact 2002 to a top source/drain contact (not shown).

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor device, comprising:
a first semiconductor structure extending along a vertical direction;
a high-k dielectric layer disposed around at least the first semiconductor structure;
a first metal structure disposed around the first semiconductor structure, with the high-k dielectric layer interposed therebetween;
a ferroelectric structure disposed around the first semiconductor structure, with the high-k dielectric layer and the first metal structure interposed therebetween; and
a second metal structure having a portion disposed around the first semiconductor structure, with the high-k dielectric layer, the first metal structure, and the ferroelectric structure interposed therebetween.

2. The semiconductor device of claim 1, wherein the first metal structure comprises a top surface and a bottom surface, each of the top surface and the bottom surface having a staircase profile.

3. The semiconductor device of claim 2, wherein the ferroelectric structure comprises a first portion lining the top surface of the first metal structure and a second portion lining the bottom surface of the first metal structure.

4. The semiconductor device of claim 1, further comprising:
a second semiconductor structure in contact with a bottom surface of the first semiconductor structure; and
a third second semiconductor structure in contact with a top surface of the first semiconductor structure.

5. The semiconductor device of claim 4, wherein the first semiconductor structure has a first conductivity, while the second and third semiconductor structures have a second conductivity.

6. The semiconductor device of claim 4, wherein the high-k dielectric layer is disposed around also the third semiconductor structure.

7. The semiconductor device of claim 4, further comprising:
a first contact structure in electrical connection with the second semiconductor structure; and
a second contact structure in electrical connection with the third semiconductor structure.

8. The semiconductor device of claim 7, wherein the first contact structure has a lateral portion around the second semiconductor structure, and a vertical portion in parallel with a combination of the second semiconductor structure, the first semiconductor structure, and the third semiconductor structure.

9. The semiconductor device of claim 7, wherein the second contact structure is wrapped by the high-k dielectric layer.

10. The semiconductor device of claim 1, wherein the second metal structure, the ferroelectric structure, and the first metal structure operatively form a first capacitor with a first capacitance, and the first metal structure, the high-k dielectric layer, and the first semiconductor structure operatively form a second capacitor with a second capacitance.

11. The semiconductor device of claim 10, wherein the first capacitance is substantially greater than the second capacitance.

12. A memory device, comprising:
a memory cell consisting of a transistor and a capacitor;
wherein the transistor comprises:
a first semiconductor structure extending along a vertical direction;
a second semiconductor structure disposed below the first semiconductor structure;
a third semiconductor structure disposed above the first semiconductor structure;
a high-k dielectric layer surrounding at least the first semiconductor structure and the third semiconductor structure; and
a first metal structure surrounding the first semiconductor structure, with the high-k dielectric layer interposed therebetween;
wherein the capacitor comprises:
the first metal structure;
a ferroelectric structure surrounding the first semiconductor structure, with the high-k dielectric layer and the first metal structure interposed therebetween; and
a second metal structure having a portion surrounding the first semiconductor structure, with the high-k dielectric layer, the first metal structure, and the ferroelectric structure interposed therebetween.

13. The memory device of claim 12, wherein the first metal structure comprises a top surface and a bottom surface, each of the top surface and the bottom surface having a staircase profile.

14. The memory device of claim 13, wherein the ferroelectric structure comprises a first portion lining the top surface of the first metal structure and a second portion lining the bottom surface of the first metal structure.

15. The memory device of claim 12, wherein the first semiconductor structure has a first conductivity, while the second and third semiconductor structures have a second conductivity.

16. The memory device of claim 12, further comprising:
a first contact structure in electrical connection with the second semiconductor structure; and
a second contact structure in electrical connection with the third semiconductor structure.

17. The memory device of claim 16, wherein the first contact structure has a lateral portion surrounding the second semiconductor structure, and a vertical portion in parallel with a combination of the second semiconductor structure, the first semiconductor structure, and the third semiconductor structure.

18. A method for fabricating semiconductor devices, comprising:
vertically etching a stack comprising a first dielectric layer, a second dielectric layer, and a third dielectric layer to form a vertical opening;
laterally etching the second dielectric layer to form a recess;
forming a first metal structure lining an inner sidewall of the recess, a first portion of a top surface of the recess, and a first portion of a bottom surface of the recess;
forming a ferroelectric structure lining an inner sidewall of the first metal structure, a second portion of the top surface of the recess, and a second portion of the bottom surface of the recess;
forming a second metal structure filling the recess;
lining an inner sidewall of the vertical opening with a high-k dielectric layer; and
forming a first semiconductor structure inside the vertical opening that is wrapped by the high-k dielectric layer, the second metal structure, the ferroelectric structure, and the first metal structure.

19. The method of claim 18, further comprising:
prior to lining the inner sidewall of the vertical opening with the high-k dielectric layer, epitaxially growing a second semiconductor structure;
subsequently to forming the first semiconductor structure, epitaxially growing a third semiconductor structure.

20. The method of claim 19, further comprising:
forming a first contact structure in electrical connection with the second semiconductor structure, wherein the first contact structure comprises a lateral portion surrounding the second semiconductor structure; and
forming a second contact structure in electrical connection with the third semiconductor structure, wherein the second contact structure is disposed above the third semiconductor structure.
